(19) United States
(12) Patent Application Publication
(10) Pub. No.: US 2025/0298324 A1
(43) Pub. Date: Sep. 25, 2025

(54) METHOD AND DEVICE FOR MASK INSPECTION

(71) Applicant: Carl Zeiss SMT GmbH, Oberkochen (DE)

(72) Inventors: Ulrich Matejka, Jena (DE); Lutz Brekerbohm, Hardegsen (DE)

(21) Appl. No.: 19/231,707

(22) Filed: Jun. 9, 2025

Related U.S. Application Data
(63) Continuation of application No. PCT/EP2023/083715, filed on Nov. 30, 2023.

(30) Foreign Application Priority Data
Dec. 19, 2022 (DE) 102022133829.0

(51) Int. Cl. G03F 7/00; H04N 25/768

(52) U.S. Cl. CPC G03F 7/7065; G03F 7/70033; G03F 7/706851; G03F 7/70891; H04N 25/768

(57) ABSTRACT

A method and a device for mask inspection, wherein the mask is designed for operation in reflection at an operating wavelength of less than 30 nm and is intended to be illuminated in a lithography process in a projection exposure apparatus for exposing a wafer. In an exemplary method, an object field situated in an object plane (OP) and illuminated with EUV radiation having a wavelength of less than 30 nm by way of an illumination system is imaged by a projection lens onto an image field situated in an image plane (IP), wherein a sensor arrangement (having a plurality of sensors is situated in the image plane, wherein the mask is guided over the object field in the object plane in a scanning operation, and wherein an image of the mask is formed by combining sensor images captured by each of the individual sensors in the scanning operation.

### CROSS-REFERENCE TO RELATED APPLICATIONS

This application is a continuation-in-part of and claims benefit under 35 U.S.C. § 120 from PCT Application No. PCT/EP2023/083715, filed on Nov. 30, 2023, which claims priority from German Application No. 10 2022 133 829.0, filed on Dec. 19, 2022. The entire contents of each of these earlier applications are incorporated herein by reference.

### TECHNICAL FIELD

The invention relates to a method and a device for mask inspection.

### BACKGROUND

Microlithography is used for producing microstructured components, such as integrated circuits or LCDs, for example. The microlithography process is carried out in a so-called projection exposure apparatus comprising an illumination device and a projection lens. In this case, the image of a mask (=reticle) illuminated by use of the illumination device is projected by use of the projection lens onto a substrate (e.g. a silicon wafer) that is coated with a light-sensitive layer (photoresist) and arranged in the image plane of the projection lens, in order to transfer the mask structure to the light-sensitive coating of the substrate.

In the lithography process, unwanted defects on the mask have a particularly disadvantageous effect since they can be reproduced with each exposure step and there is thus the risk of the entire production of semiconductor components being unusable in the worst case. It is therefore of great importance to test the mask for sufficient imaging capability before it is used in mass production.

Consequently, there is a need to test the mask quickly and simply, specifically as much as possible under conditions which are similar to those really present in the projection exposure apparatus. For this purpose, it is known to use devices for mask inspection which in turn comprise an illumination system and a projection lens, the illuminated region of the mask being imaged onto a sensor arrangement, such as e.g. a CCD camera, by use of the projection lens. In this case, in practice the problem occurs, inter alia, that the imaging result that ultimately results as the result of the lithography process on the wafer or in the light-sensitive layer (photoresist) thereof in the projection exposure apparatus still differs from the result predicted on the basis of the intensity measurement performed using the sensor arrangement in the mask inspection apparatus.

Avoiding or alleviating this problem is a demanding challenge, particularly in the inspection of masks designed for operation in the EUV (i.e. at wavelengths of less than 30 nm, in particular less than 15 nm). In this regard, for instance, a characterization—possible in principle—of the relevant (EUV) masks at higher wavelengths in the DUV range (e.g. at approximately 248 nm or approximately 193 nm), owing to the significant deviation from the actual operating wavelength of the projection exposure apparatus, leads to losses with regard to the mask inspection reliability for instance to the effect that, e.g., specific particles or defects on the mask are not recognized at all, defects owing to imaging with a deviating wavelength are represented differently relative to their optical effect in the projection exposure apparatus, or defects are incorrectly recognized at positions at which no defect at all is present, the resolution achieved also being reduced owing to the transition to higher wavelengths in mask inspection.

On the other hand, a transition—desirable in principle against the background above—to lower (in particular EUV) wavelengths in mask inspection leads to the further problem that fundamentally the EUV radiation then typically generated by way of a plasma light source in the device for mask inspection cannot be reduced to a sufficiently small image field or image field corresponding to the typical dimensions of available sensors. This problem is attributable to the circumstance that the plasma light source required for generating the EUV radiation, in contrast to the excimer lasers used in the DUV range, initially emits in all spatial directions and, owing to maintenance of the etendue, concentration of the EUV radiation generated onto a sufficiently small image field is not straightforwardly possible without at the same time also accepting a loss of light.

### SUMMARY

Against the background above, it is an aspect of the present invention to provide a method and a device for mask inspection which enable as accurate a prediction as possible of the imaging result that results as the result of the lithography process on the wafer, while at least partly avoiding the problems described above.

This aspect is achieved by use of the method according to the features of independent Claim 1 and the device according to alternative independent Claim 31.

In accordance with one aspect, the invention relates to a method for mask inspection, wherein the mask is designed for operation in reflection at an operating wavelength of less than 30 nm and is intended to be illuminated in a lithography process in a projection exposure apparatus for exposing a wafer,
wherein an object field situated in an object plane and illuminated with EUV radiation having a wavelength of less than 30 nm by way of an illumination system is imaged by a projection lens onto an image field situated in an image plane, wherein a sensor arrangement having a plurality of sensors is situated in the image plane;
wherein the mask is guided over the object field in the object plane in a scanning operation; and
wherein an image of the mask is formed by combining sensor images captured by each of the individual sensors in the scanning operation.

The invention is based on the concept, in particular, of performing the inspection of a mask designed for operation in the EUV, or intended for use in an EUV projection exposure apparatus, likewise using EUV radiation (i.e. in particular “actinically”) and at the same time overcoming the fundamental problem—described in the introduction—of the comparatively large image fields that then have to be handled in mask inspection by virtue of the fact that in the method and the device according to the invention for mask inspection, the respective image of the mask is formed by combining a plurality of sensor images captured by each sensor of a plurality of sensors of the sensor arrangement according to the invention in a scanning operation.

In this case, the invention further includes the principle—realized hereinafter on the basis of various embodiments—of using skillful geometric arrangement of the individual sensors in the sensor arrangement to attain the highest possible luminous efficiency insofar as the largest possible proportion of the image field is effectively filled with active sensor area or active sensor pixels. The invention here in turn preferably further includes the concept of maximizing a “line filling rate”—defined below—in the sense of active sensor area constituting the largest possible percentage proportion of the image field length exposed in the scanning operation. Furthermore, the advantageous geometric arrangement of the individual sensors in embodiments of the invention includes in particular the relative arrangement thereof in such a way that, e.g., a certain minimum number of the sensors swept over in each case in the scanning operation is ensured and/or a predefined number of sensor series not swept over in each case in the scanning operation is not exceeded.

As a result, a particularly accurate and reliable mask inspection is thus realized according to the invention by virtue of the fact that, firstly, the fundamental advantages of an actinic mask inspection (i.e. mask inspection carried out with an “inspection wavelength” corresponding to the actual operating wavelength of the mask in the projection exposure apparatus) are achieved and, secondly, problems that are in principle concomitant with the transition to the EUV wavelength range in mask inspection on account of the relatively large image fields to be managed in this case are overcome.

In accordance with one embodiment, as sensors of the sensor arrangement, TDI sensors (TDI=“Time Delay and Integration”) having a sensor area are used, wherein only a part of the respective sensor area is embodied as active sensor area with active sensor pixels. With regard to configurations of TDI sensors known per se, reference is made merely by way of example to DE 197 14 221 A1 and U.S. Pat. No. 6,429,897, the entire contents of both documents are incorporated by reference.

In accordance with one embodiment, in the scanning operation, the projections of different regions of the mask sweep over the sensor arrangement along different scan lines.

In accordance with one embodiment, a line filling rate, which is defined for each of said scan lines as a ratio between the distance covered in each case with active sensor pixels in the scanning operation and the image field length exposed in the scanning operation in the scanning direction, is in each case not less than 25% for any of the scan lines, in particular not less than 35% for any of the scan lines, more particularly not less than 50% for any of the scan lines. Here and hereinafter, the “scanning direction” is understood to mean that direction in which the projection of the mask moves in the image plane during the scanning operation.

In accordance with one embodiment, in the scanning operation for each of the scan lines the number of sensors swept over in each case is at least one, in particular at least two, more particularly at least three.

In accordance with one embodiment, the sensors of the sensor arrangement form a plurality of sensor series arranged next to one another in the scanning direction and running transversely with respect to the scanning direction.

In accordance with one embodiment, in the scanning operation for each of the scan lines the number of sensor series not swept over in each case is at most two, in particular at most one.

In accordance with one embodiment, sensor series adjacent to one another are offset relative to one another in a direction running transversely with respect to the scanning direction. In this case, this offset can be chosen in particular such that at least one sensor of a sensor series partly overlaps two sensors of an adjacent sensor series.

In accordance with one embodiment, active sensor areas of the sensors are arranged asymmetrically on a respective sensor area, wherein the asymmetries of different sensors are oriented differently.

In accordance with one embodiment, forming the sensor arrangement by combining the sensors involves carrying out sorting on the basis of a prior determination of defective regions of the respective sensors. This takes account of the circumstance that in general, owing to the dictates of production, individual sensors have so-called “dead lines”, which are defective insofar as they always yield a zero signal or a maximum sensor signal. Instead of such sensors being completely sorted out, they can be suitably “sorted”, as described in even greater detail hereinafter, in which case e.g. dead lines are avoided or not permitted where only a comparatively small number of sensors of the sensor arrangement are situated.

In accordance with one embodiment, the image field of the projection lens has an obscuration in the form of a region that is shaded during the imaging.

In accordance with one embodiment, the obscuration lies at least partly within the image field. In this case, a part of the image field can be situated in particular on each side of the optical axis. Furthermore, a part of the image field can be situated on each side of the obscuration. More particularly, the obscuration can be arranged symmetrically about a rotation axis of the projection lens.

In accordance with one embodiment, a readout of the data captured by each of the individual sensors in the scanning operation is synchronized with the guiding of the mask over the object field. In this case, “synchronizing” should be understood to mean that the speed of movement of the mask (in millimetres per second) multiplied by the imaging scale of the projection lens corresponds to the readout frequency of the sensors (in kHz) multiplied by the size of the sensor pixels measured in the scanning direction. In other words, the readout speed of the sensors must be implemented more rapidly than the movement of the mask by a factor, where this factor is the imaging scale of the projection lens.

In accordance with one embodiment, a calibration of the respective brightness of the sensor images captured by each of the individual sensors in the scanning operation is carried out on the basis of an intensity measurement carried out using an intensity sensor.

In accordance with one embodiment, at least two sensors or sensor regions of the sensor arrangement are read at mutually different readout frequencies. This configuration can take account of the circumstance that in scenarios in which not all of the sensors are mounted exactly in one plane or some of the sensors are not mounted exactly parallel to this plane or in which the optical unit used has a distortion, the effective imaging scale for the individual sensors may be slightly different. Since the imaging scale is a concomitant influence when the readout of the data captured by each of the individual sensors in the scanning operation is synchronized with the guiding of the mask over the object field, an unwanted image blur and thus a reduction of contrast occur during a readout from all sensors at the same readout frequency as a result of the TDI process. This effect can be avoided or at least reduced by each sensor being read at an optimum readout frequency for it, and/or by respectively different sensor regions of one and the same sensor being read at different readout frequencies.

In accordance with one embodiment, combining the sensor images of the sensors is preceded by preprocessing the sensor images. This preprocessing can comprise e.g. low-pass filtering. Furthermore, prior to their addition, the sensor images of individual sensors can, with sub-pixel accuracy, be displaced and/or enlarged or reduced and/or distorted. As a result, the scale differences mentioned above can be at least partly compensated for.

In accordance with one embodiment, the dark current of the sensors is measured and then subtracted from the measurement results.

In accordance with one embodiment, the sensors are cooled for noise reduction purposes. In this case, the sensors can be cooled in particular to a temperature that is lower than the average temperature of the projection lens (for example to a temperature of 10° C., 0° C. or −20° C.). The cooling can be effected e.g. by way of a cooling fluid and/or by way of Peltier elements. This can take account of the circumstance that so-called dark current noise may increase over the lifetime of the sensor arrangement, the aforementioned cooling or adaptation of the operating temperature then enabling the dark current noise to be reduced (e.g. to the value originally given for the “new” sensor arrangement).

The invention further also relates to a sensor arrangement comprising a plurality of sensors, wherein the sensors form a plurality of sensor series arranged next to one another in a predefined direction and running transversely with respect to the predefined direction, wherein a line filling rate, which is defined for each line running parallel to the predefined direction over a predefined image field, which is at least partly covered by the sensor arrangement, as a ratio between the distance covered in each case with active sensor pixels and the entire image field length in the predefined direction, is in each case not less than 25% for any of the lines.

In accordance with one embodiment, the line filling rate is not less than 35% for any of said lines, more particularly not less than 50% for any of said lines.

In accordance with one embodiment, the sensors are designed for an operating wavelength of less than 30 nm.

The invention further also relates to a sensor arrangement comprising a plurality of sensors, wherein the sensors form a plurality of sensor series arranged next to one another in a predefined direction and running transversely with respect to the predefined direction, wherein the sensors are designed for an operating wavelength of less than 30 nm.

In accordance with one embodiment, the sensors are configured as TDI sensors.

In accordance with one embodiment, sensor series adjacent to one another are offset relative to one another in a direction running transversely with respect to the predefined direction.

In accordance with one embodiment, this offset is chosen such that at least one sensor of a sensor series partly overlaps two sensors of an adjacent sensor series.

In accordance with one embodiment, each of the sensors has a sensor area, wherein in the case of each of the sensors only a part of the respective sensor area is embodied as active sensor area with active sensor pixels.

In accordance with one embodiment, the active sensor areas are arranged asymmetrically on a respective sensor area, wherein the asymmetries of different sensors are oriented differently.

In accordance with one embodiment, the sensor arrangement is formed by combining the sensors in such a way that the sensors are sorted on the basis of defective regions present on the respective sensors.

In accordance with one embodiment, the sensor arrangement comprises a cooling device.

The sensor arrangement can be designed in particular for use in a method having the features described above.

The invention further relates to a device for mask inspection, wherein the mask is designed for operation in reflection at an operating wavelength of less than 30 nm and is intended to be illuminated in a lithography process in a projection exposure apparatus for exposing a wafer, wherein the device comprises an illumination system, a projection lens and a sensor arrangement, wherein an object field situated in an object plane and illuminated with EUV radiation having a wavelength of less than 30 nm by way of the illumination system is imaged by a projection lens onto an image field situated in an image plane, wherein a sensor arrangement having a plurality of sensors is situated in the image plane, and wherein the device comprises a sensor arrangement having the features described above.

The device can be designed in particular to carry out a method having the features described above.

For advantages and advantageous configurations of the sensor arrangement and of the device, reference is made to the above embodiments in association with the method according to the invention.

Further configurations of the invention can be gathered from the description and the dependent claims.

The invention is explained in greater detail below on the basis of preferred exemplary embodiments with reference to the accompanying drawings.

### BRIEF DESCRIPTION OF DRAWINGS

In the figures:

FIG. 1 shows a schematic illustration for elucidating a problem addressed by the invention;

FIG. 2 shows a schematic illustration for elucidating one possible embodiment of a method according to the invention, and of a sensor arrangement used in the method;

FIGS. 3-11 show schematic illustrations for elucidating further possible embodiments of a method according to the invention, and of a sensor arrangement used in the method;

FIG. 12 shows a schematic illustration of the fundamental possible set-up of a projection lens used in a device according to the invention for mask inspection; and

FIG. 13 shows a schematic illustration of the fundamental possible set-up of a device for mask inspection used in the method according to the invention.

### DETAILED DESCRIPTION

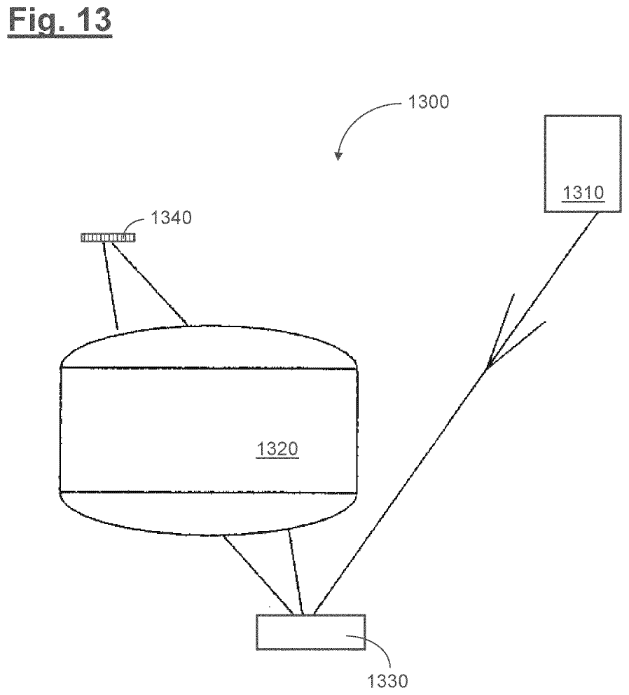

As is illustrated merely schematically in FIG. 13, a device 1300 for mask inspection that is usable in the method according to the invention comprises an illumination system 1310 and a projection lens 1320, wherein light from a light source (not illustrated in FIG. 13) enters the illumination system 1310 and is incident on a mask 1330 arranged in the object plane of the projection lens 1320, and wherein the illuminated region of the mask 1330 is imaged onto a sensor arrangement 1340 by way of the projection lens.

Here and in the following, the photo mask can in particular have an aspect ratio having a value in the range from 1:1 to 1:3, preferably a value in the range from 1:1 to 1:2, more preferably a value of 1:1 or 1:2. The mask can have a substantially rectangular shape. The mask can preferably have a length and width in the range from 5 inches to 7 inches, more preferably a length and width of 6 inches. Alternatively, the mask can have a length in the range from 5 inches to 7 inches and a width in the range from 10 inches to 14 inches, preferably a length of 6 inches and a width of 12 inches.

In order to make a prediction of the imaging result attained with a mask when carrying out the lithography process in a projection exposure apparatus, firstly an intensity distribution obtained for the mask in the device for mask inspection from FIG. 13 or by use of the sensor arrangement is measured. In this case, the same wavelength that is also used in the lithography process in the projection exposure apparatus is preferably used in the mask inspection apparatus.

Below is a brief description of an example of a scanning measurement. In some implementations, during a scanning operation, the illumination system 1310, the projection lens 1320, and the sensor arrangement 1340 remain stationary while the mask 1330 moves. To measure the mask, the mask is located on a mask stage and moves with a constant speed. The projection lens is resting and projects an image of the mask onto the sensor array arranged in the image plane. Thus, on each sensor there appears a moving image. The movement speed of the image is the stage speed times/multiplied with the magnification factor of the projection lens. Each sensor is configured as a TDI sensor, i.e., the collected photo electrons move electronically from one pixel to the neighboring pixel in the readout direction. When the electrons reach the last pixel row, they go to the readout electronics, which can be analog-to-digital (A/D) converters. This charge transfer from one pixel to the next, i.e., moving of the image within the sensor happens during illumination. The speed the image moves (electronically) within the sensor is synchronized to the movement speed of the optical image with a very high accuracy. The movement direction is also synchronized. Thus, it is possible to measure a large area of the mask during movement without the need to stop the mask and accelerate it several times per mm. An example of this technique of TDI imaging is described in German patent publication DE 197 14 221 A1 and U.S. Pat. No. 6,429,897.

In some implementations, the sensor arrangement includes several sensors. When scanning the mask, each part of the mask is seen by 3 or 4 sensors. The images of these sensors are added electronically (with appropriate time delay to account for the fact that one part of the mask passes the 3 or 4 sensors after another) to form one total result image.

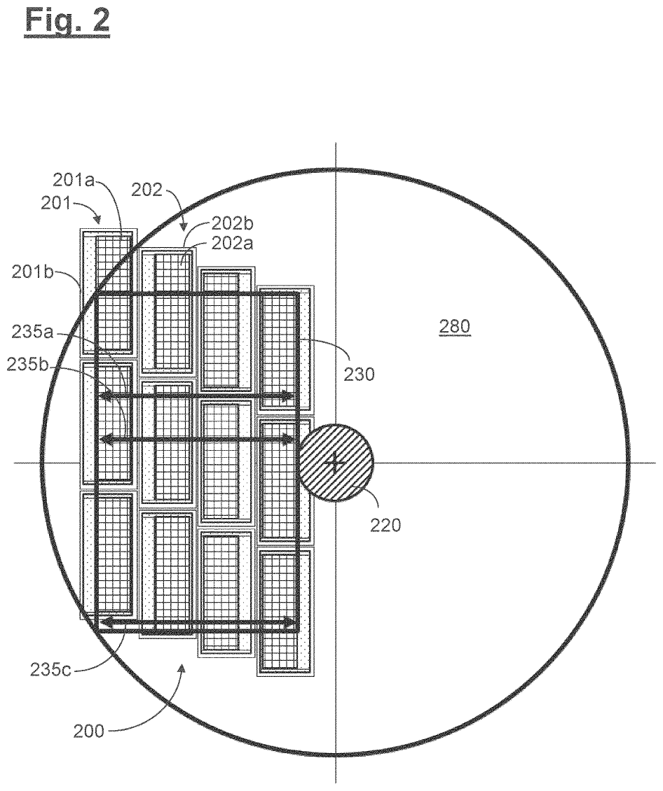

As a simplified explanation, in FIG. 2, suppose each TDI sensor has 5 stages, when a scan line spans four TDI sensors, the 5 stages of the four TDI sensors combine, such that the TDI sensor arrangement now effectively has 20 stages. The photoelectrons collected over the 5 stages within each TDI sensor are accumulated analogously and all photoelectrons are transferred to the readout stage (i.e., the analog-to-digital-converter)). The signals of the 4 TDI sensor are added digitally using an image processing computer. Before adding the images of the 4 TDI sensors they may be shifted in the x and y directions (i.e., in scan-direction and cross-scan-direction) with sub pixel accuracy to make the positions fit to each other. In a practical system, typically, a TDI sensor has 128 or 256 or 512 stages. In some examples, a TDI sensor can have 1000 or 4000 stages, or even more stages.

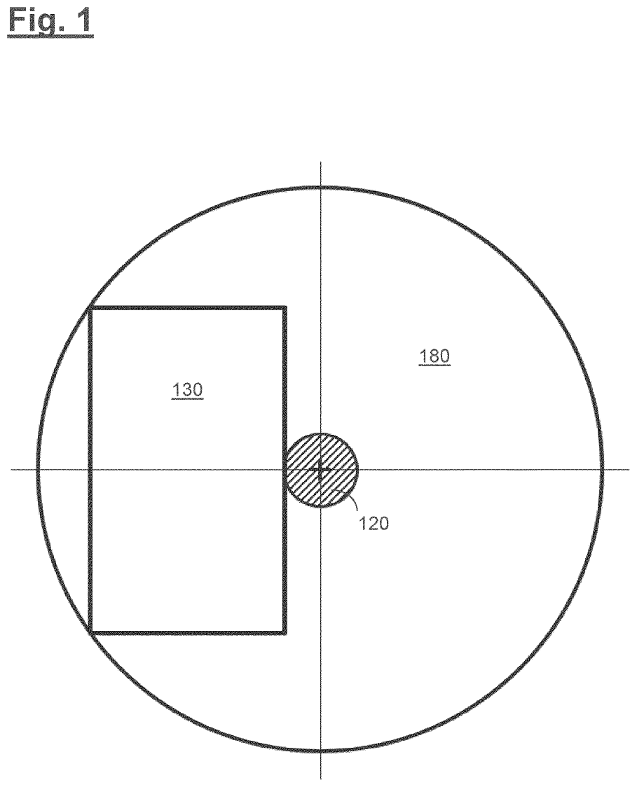

In the schematic illustration in FIG. 1, “180” denotes an image field that is able to be imaged overall by way of the imaging optical unit or the projection lens of the device for mask inspection, “120” denotes an obscuration (in the form of a region that is shaded during the imaging), which will be described in even greater detail, and “130” denotes a rectangular image field onto which the object field situated in the object plane of the projection lens is imaged. A sensor arrangement—described hereinafter—comprising a plurality of sensors is situated in the image plane of the projection lens.

In some examples, a small part of the mask (less than 1×1 mm²) is illuminated by the illumination system with illumination light. The size of the image field 130 is the size of the illumination field multiplied by the magnification of the imaging optics. Ideally the whole image field is filled with sensors. The imaging optics is able to image the imaging field (plus some margin). In theory the optics can image a circular field (180). In practice the optics can image only a part of the field 180 (usually the field 130 plus some margin) because the optical elements are not larger.

Hereinafter, a description is given for explaining various embodiments of a method according to the invention and of a sensor arrangement used therein for mask inspection with reference to the schematic illustrations in FIG. 2 to FIG. 11.

What the embodiments described hereinafter have in common is that for the inspection of masks designed for operation in the EUV wavelength range in the device according to the invention for mask inspection EUV radiation is likewise used and—in order to manage the comparatively large image fields that are fundamentally concomitant therewith during the imaging of the mask in the projection exposure apparatus—a scanning process is realized in such a way that an image of the mask is formed by combining sensor images respectively captured by individual sensors of a sensor arrangement in the scanning operation. Here the embodiments described below with reference to FIG. 2 et seq. correspond to different, in each case particularly “skillful” or advantageous geometric arrangements of the sensors for the purposes of the highest possible luminous efficiency.

The actual scanning operation can be carried out here in such a way that the image field in regard to the device for mask inspection is guided over the sensor arrangement at a constant speed of the order of magnitude of a few millimeters per second, for example.

As sensors of the sensor arrangement, use is made here of TDI sensors, the images of which are added with a corresponding time offset. In a manner known per se, each of these TDI sensors has, on a carrier (typically produced from ceramic material), active sensor pixels only on a part (forming the “active sensor area”) of the entire sensor surface area. It is ideal if the active area of the sensor covers a fraction of the total sensor area as large as possible. Even more ideal if the active area covers the whole sensor area. But in many cases, this is not possible to manufacture because the readout electronics (e.g., A/D-converters) and other supplementary electronics and the electric interconnections cover some part of the total sensor area. Merely by way of example (and without the invention being restricted thereto) the dimensions of the carriers according to individual sensors in an exemplary embodiment which is illustrated in FIG. 2 and described below can be 68 mm*30 mm, the sensor surface area can be 64 mm*26 mm and the active sensor area can be 60 mm*18 mm.

In a merely schematic illustration, FIG. 2 shows a sensor arrangement 200 comprising a total of 12 sensors 201, 202, . . . , the active sensor areas of which are designated by “201a”, “202a”, . . . . A carrier of the sensors 201, 202, . . . , said carrier typically being produced from ceramic material, is respectively designated by “201b”, “202b”, . . . .

The image field guided over the sensor arrangement 200 in the scanning operation mentioned above is designated by “230”. “280” denotes for comparison the image field (having an exemplary diameter of 308 mm) that is able to be imaged overall by way of the imaging optical unit or the projection lens of the device for mask inspection, and “220” denotes an obscuration present (in the form of a region that is shaded during the imaging), which is provided in the exemplary embodiment shown (but once again without restriction of the invention in this regard) and which will be discussed in even greater detail hereinafter.

As is indicated schematically by way of the double-headed arrows depicted in FIG. 2, in the scanning operation during the imaging of the respectively illuminated region of the mask onto the image field, the projections of different regions of the mask sweep over the sensor arrangement along different scan lines (of which three scan lines are depicted merely by way of example in FIG. 2 and are designated by “235a”, “235b” and “235c”). Imagine any feature (e.g., one pinhole) on the photo mask. When the mask moves in the scan direction, the image of the feature will move along a line over the sensor array. This (virtual) line is referred to as a scan line. Every feature on the mask corresponds to a different scan line. In the exemplary embodiment in accordance with FIG. 2, the geometric arrangement of the sensors 201, 202, . . . is chosen such that the respective active sensor area 201a, 202a, . . . of at least three sensors 201, 202, . . . is swept over for each of said scan lines. In other words, during the scanning operation, the image of each region of the mask is swept over the active sensor areas of at least three sensors in the sensor arrangement along a path represented by the corresponding scan line. In this case, the scan can take place both from left to right and from right to left.

A criterion that is suitable in particular for the maximally efficient utilization according to the invention of the active sensor areas in the scanning process is the ratio of the distance covered in each case with active sensor pixels in the scanning operation and the image field length exposed in the scanning operation, said ratio being referred to here and hereinafter as “line filling rate”. Preferably, the geometric arrangement of the individual sensors relative to one another in the sensor arrangement according to the invention is chosen here such that the line filling rate defined above is not less than 25% for any of the scan lines, in particular not less than 35% for any of the scan lines, more particularly not less than 50% for any of the scan lines. In the specific exemplary embodiment in FIG. 2, this line filling rate is 51% for those scan lines which sweep over the respective active sensor areas of three sensors, and 68% for those scan lines or trajectories which sweep over four sensors. The higher the scan line fill rate the more light is collected by the sensors, so a high fill rate helps improve sensitivity. For example, if the scan line fill rate is 25%, that means 25% of the light reaching the image field will be detected by the active area of the sensors and 75% of the light is lost.

In accordance with FIG. 2, the sensors 201, 202, . . . of the sensor arrangement 200 form a plurality of sensor series arranged next to one another in the scanning direction and running transversely with respect to the scanning direction. In this case, sensor series adjacent to one another are offset relative to one another in a direction running transversely with respect to the scanning direction. Furthermore, the respective active sensor areas 201a, 201b, . . . of the sensors 201, 202, . . . in accordance with FIG. 2 are arranged asymmetrically on the respective sensor area, wherein in addition the asymmetries of different sensors are oriented differently in part. In the specific exemplary embodiment in FIG. 2, in particular, the two sensor series illustrated on the left, relative to the two sensor series illustrated on the right, are arranged in a manner rotated by 180° with regard to their respective active sensor area. It is thereby possible to achieve the attained line filling rate with a comparatively smaller size of the image field 230 (having dimensions of 178 mm*106 mm in the example). A further advantageous effect of this geometric arrangement of the sensors 201, 202 with regard to their respective active sensor area 201a, 202a, . . . is the more uniform distribution of the thermal load acting during operation over the entire area of the sensor arrangement, which is advantageous in regard to the design of a corresponding cooling device. The readout areas shown as dotted regions in FIG. 2 produce most of the heat. As a result of the sensor arrangement shown, these readout areas are relatively far apart and evenly distributed over the surface of the sensor array. As a result, the sensor array can be cooled more effectively and evenly, and a possible temperature gradient across the sensor array is reduced. Moreover, one advantage of this asymmetric arrangement consists in the compensation or elimination of possible differences in the forwards and backwards modes of the sensors during the scanning operation (since e.g. along a scan line two sensors “work” forwards and two sensors “work” backwards, etc.).

Preferably, furthermore, as is likewise discernible in the exemplary embodiment in FIG. 2, the offset of mutually adjacent sensor series relative to one another in a direction running transversely with respect to the scanning direction is chosen such that at least one sensor of a sensor series partly overlaps two sensors of an adjacent sensor series. The overlap should in each case be larger than twice the positional tolerances of the individual sensors (if appropriate plus a certain allowance required for the image processing algorithms). As a result, even in the case of significant positional tolerances of the individual sensors, a sufficient overlap can be ensured in order to avoid a situation in which scan lines in the relevant region do not sweep over an active sensor area.

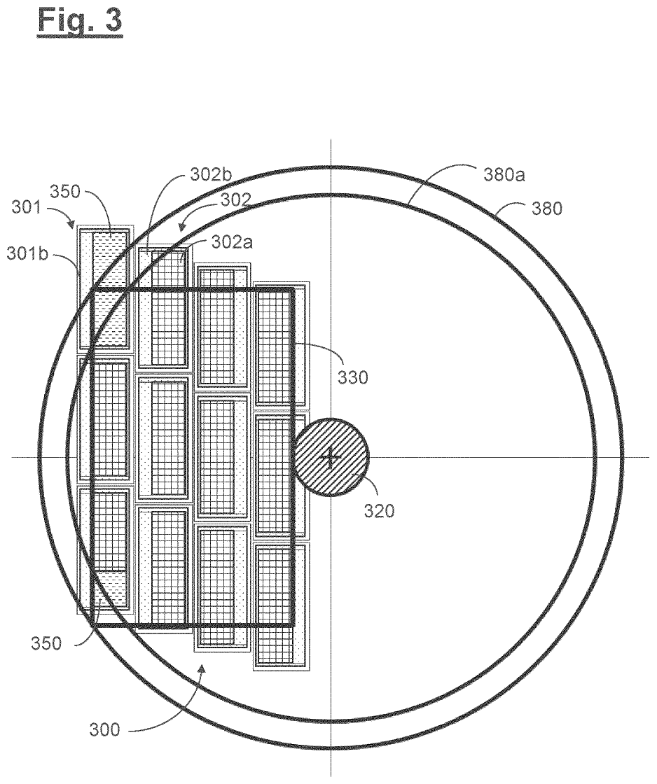

FIG. 3 shows a schematic illustration of a sensor arrangement according to the invention for elucidating a further aspect, in which case, in comparison with FIG. 2, analogous or substantially functionally identical components are designated by reference numerals increased by “100”. In FIG. 3, in addition to the image field 380 (having an exemplary diameter of 308 mm) that is able to be maximally imaged by the imaging or projection optical unit and as already indicated in FIG. 2, a further image field 380a having a comparatively smaller diameter (of 279 mm in the example) is indicated, it being assumed by way of example here that the imaging optical unit of the device for mask inspection provides a sufficiently good image quality only for the comparatively smaller image field 380a. This circumstance can be taken into account in accordance with FIG. 3 by virtue of the hatched regions 350 of the active sensor areas not being read. It is furthermore ensured in this case that each scan line in the scanning operation still sweeps over at least three sensors (the line filling rate defined above is therefore still at least 51%). The entire active area of sensor 301 is shown hatched in the example in FIG. 3. Sensor 301 can thus also be omitted in order to save production costs.

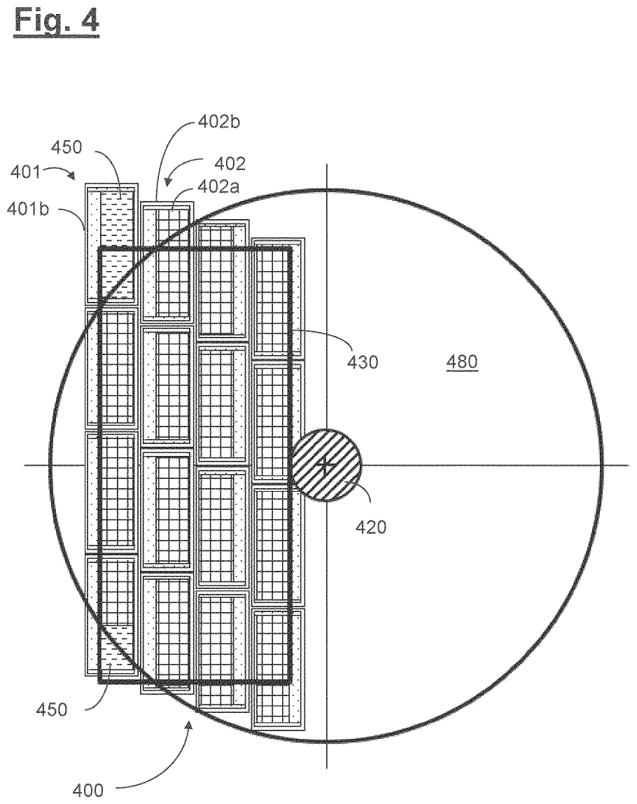

FIG. 4 shows a schematic illustration for elucidating a further possible embodiment, in which case, in comparison with FIG. 3, analogous or substantially functionally identical components are designated by reference numerals increased by “100”.

In accordance with FIG. 4, an (in comparison with FIGS. 2-3 larger) image field 430 (having exemplary dimensions of 242 mm*106 mm) is filled with 16 sensors 401, 402, . . . , it still being ensured that in the scanning operation each scan line or each imaged region of the mask still sweeps over at least three sensors (corresponding to a minimum line filling rate of 51%). In this case, the comparatively larger image field 430 has the advantage that, depending on the light source used, the light from the light source can be coupled into the illumination system of the device for mask inspection with higher efficiency or yield. In this case, the significance of the regions 450 corresponds to that of the regions 350 from FIG. 3.

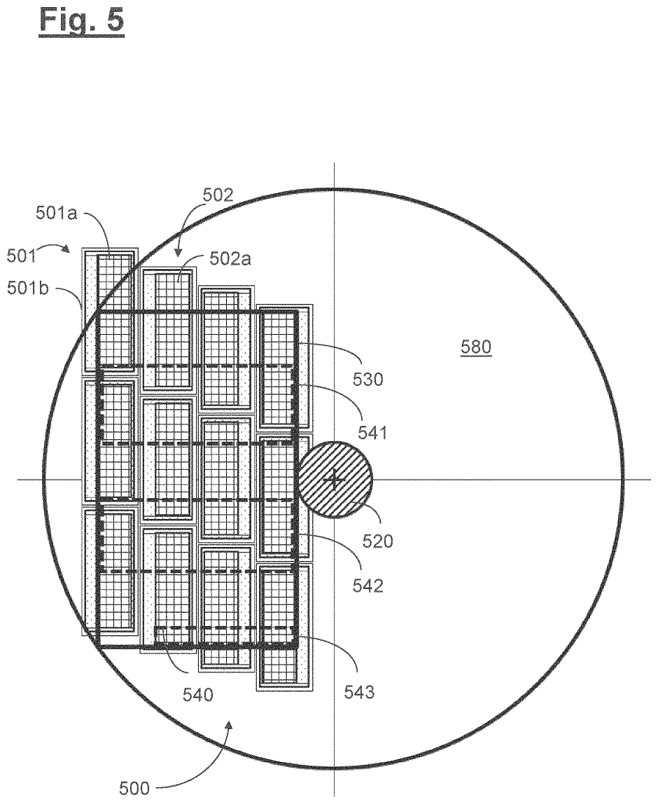

FIG. 5 shows a schematic illustration for elucidating a further aspect of the invention, in which case, in comparison with FIG. 3, analogous or substantially functionally identical components are designated by reference numerals increased by “200”. In this case, the invention is based on the consideration that individual sensors of the sensor arrangement according to the invention have so-called “dead lines”, which are defective insofar as they always yield a zero signal or a maximum sensor signal. Instead of such sensors being completely sorted out, preferably in the context of the invention they are now suitably “sorted” after the position of the relevant dead lines is determined prior to final assembly.

Specifically, in the exemplary embodiment illustrated, for instance, dead lines can be avoided or not permitted on those scan lines which are covered only by three sensors of the sensor arrangement 500. In the exemplary embodiment in FIG. 5, this means that no dead lines are permitted in the three regions 540 with dashed borders. By contrast, dead lines can be omitted in regions where four sensors are situated, although then the occurrence of two dead lines on the same scan line must be avoided. An arbitrary number of dead lines can be situated in regions situated outside the image field 530. The position of the dead lines can then be stored in a database, for example, the corresponding dead lines not being taken into consideration for the subsequent image processing. In regions where dead lines are situated, e.g. only three sensors are then available for the image evaluation.

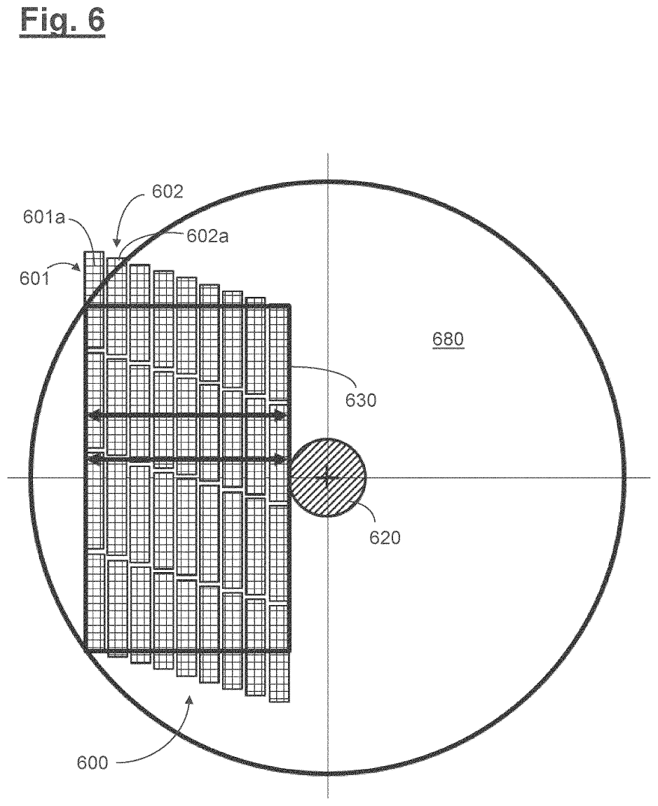

FIG. 6 shows a schematic illustration of a further embodiment, in which case, in comparison with FIG. 5, analogous or substantially functionally identical components are designated by reference numerals increased by “100”. In accordance with FIG. 6, an image field having identical dimensions in comparison with FIG. 5 is filled with a total of 36 sensors, wherein each scan line or each imaged mask region sweeps over at least 8 of these sensors. In this case, a line filling rate of 75% is achieved for the scan lines each sweeping over 8 sensors, and a line filling rate of 85% is achieved for the scan lines each sweeping over 9 sensors.

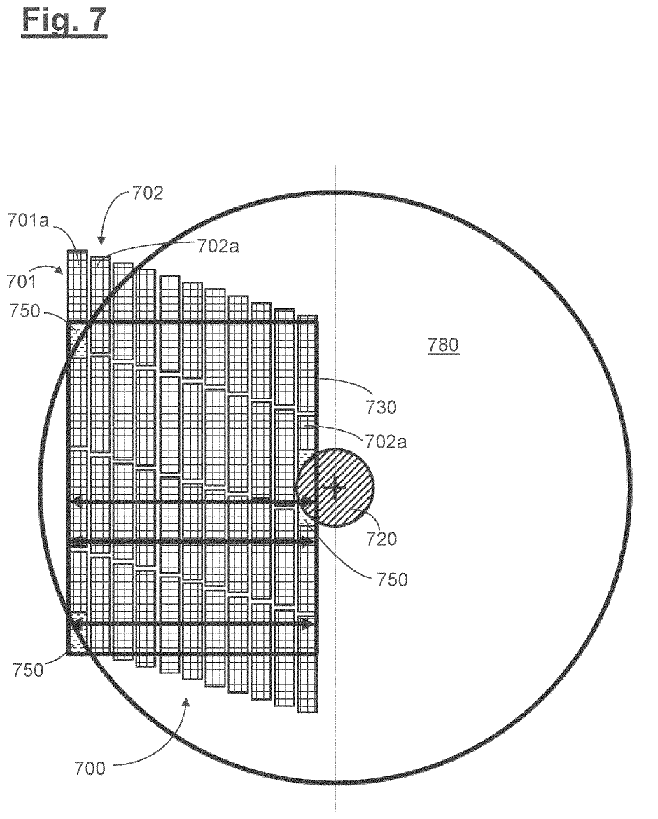

FIG. 7 shows a further exemplary embodiment, in which case, in comparison with FIG. 6, analogous or substantially functionally identical components are designated by reference numerals increased by “100”. The embodiment in FIG. 7 differs from that from FIG. 6 in the specific dimensions of the image field 730 (having values of 173 mm*130 mm), such that the aspect ratio is closer to 1:1. Depending on the light source used, this has the advantage that light from the light source can be coupled into the illumination system of the device for mask inspection with higher efficiency. What is deliberately accepted here is that one part of the image field 730 lies outside the diameter of the image field 780 that is able to be maximally imaged by the imaging optical unit, and another part of the image field 730 is shaded by the obscuration 720. In the exemplary embodiment illustrated, each scan line or each imaged mask region sweeps over at least 9 sensors and at most 11 sensors. The line filling rate is 69% for those scan lines which sweep over 9 sensors, and 85% for those scan lines which sweep over 11 sensors. Consequently, the minimum line filling rate is somewhat lower in comparison with the embodiment in FIG. 6, although the preferably square image field 730 enables a higher input coupling efficiency. For example, an EUV light source usually produces a circular light spot. If the circular light spot is squeezed into a square image field or a square homogenizing element, the fraction of light that is cut away (because it is outside the image field) is lower than if the circular light spot is squeezed into a rectangle. In this case, the significance of the regions 750 corresponds to that of the regions 350 from FIG. 3.

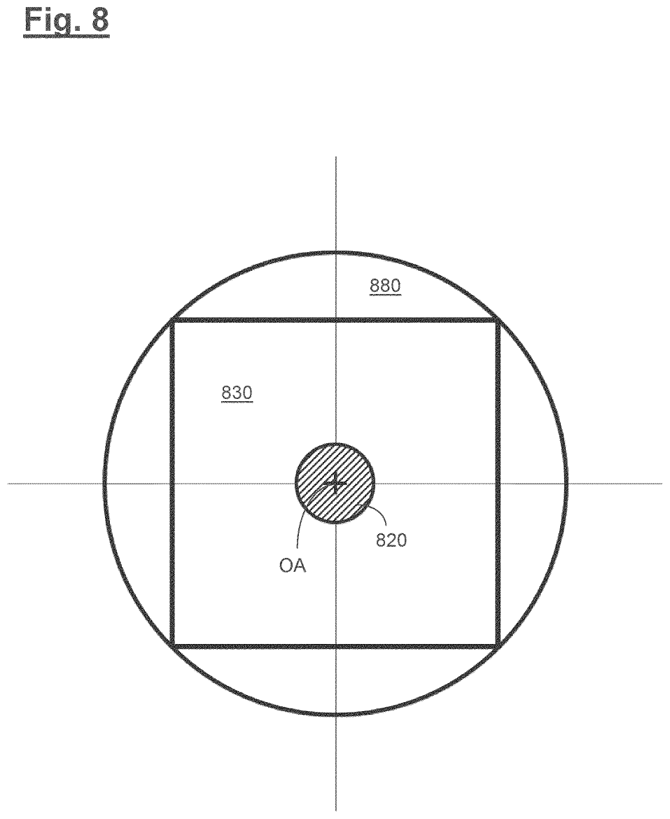

In embodiments of the invention, in particular, it is possible to effect a perpendicular imaging of the mask in the direction for mask inspection, in which case, in accordance with the schematic illustration in FIG. 8, the image field 830 extends symmetrically about the optical axis designated by “OA”. In this case, the obscuration 820 is situated in the center of the image field 830.

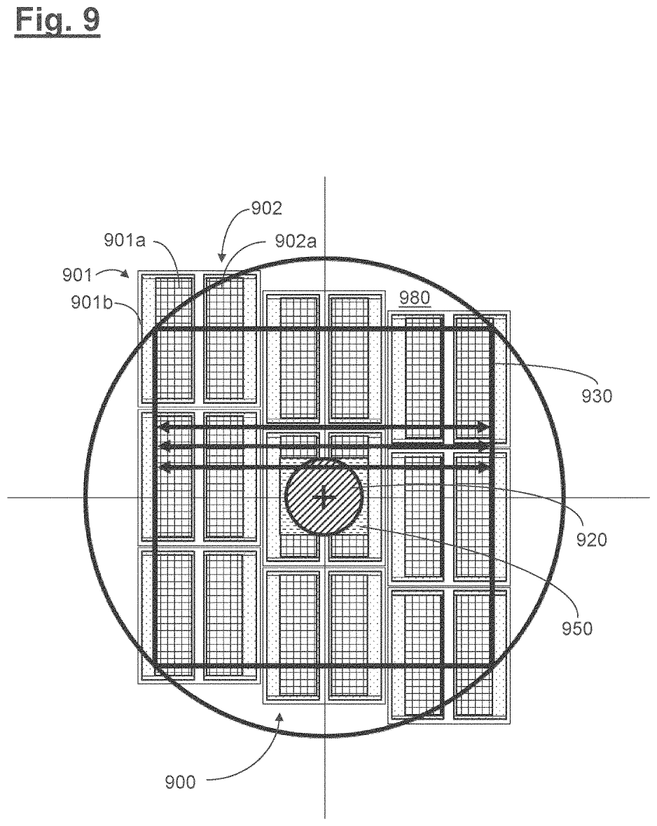

FIG. 9 shows here a suitable exemplary geometric arrangement of the sensors of the sensor arrangement, which achieves the effect that each scan line or each imaged mask region sweeps over the respective active sensor area of at least four sensors. For this purpose, the diameter of the obscuration should not exceed a predefined maximum value (of 38 mm in the example). The minimum line filling rate achieved in the exemplary embodiment illustrated is 43% (for scan lines sweeping over the active sensor areas of four sensors). In this case, the significance of the regions 950 corresponds to that of the regions 350 from FIG. 3.

With the same sensor arrangement, it is also possible to capture a somewhat larger image field having dimensions of, e.g., 168 mm*178 mm (in the case where the image field that is maximally generable by the imaging optical unit has a diameter of 245 mm), once again a minimum line filling rate of 43% being achieved. Note that a rectangle of 168 mm*178 mm has a diagonal of 244.76 mm (rounded to 245 mm). If the optics can image a diameter larger than 245 mm, the image field size can be increased a bit further in the vertical direction.

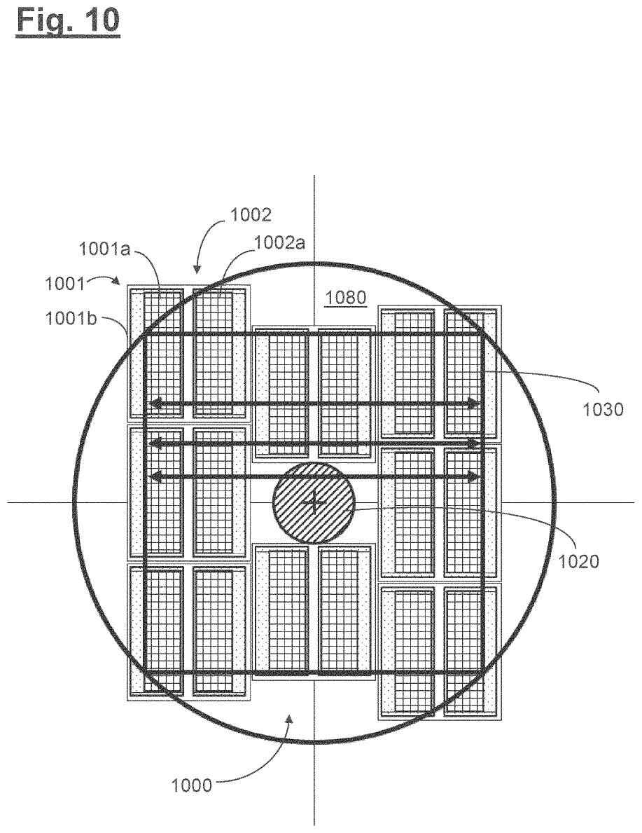

FIG. 10 shows a further exemplary embodiment with once again an image field arranged symmetrically with respect to the optical axis and an obscuration situated in the center of this image field, wherein once again each scan line or each imaged region of the mask sweeps over the respective active sensor areas of at least four sensors.

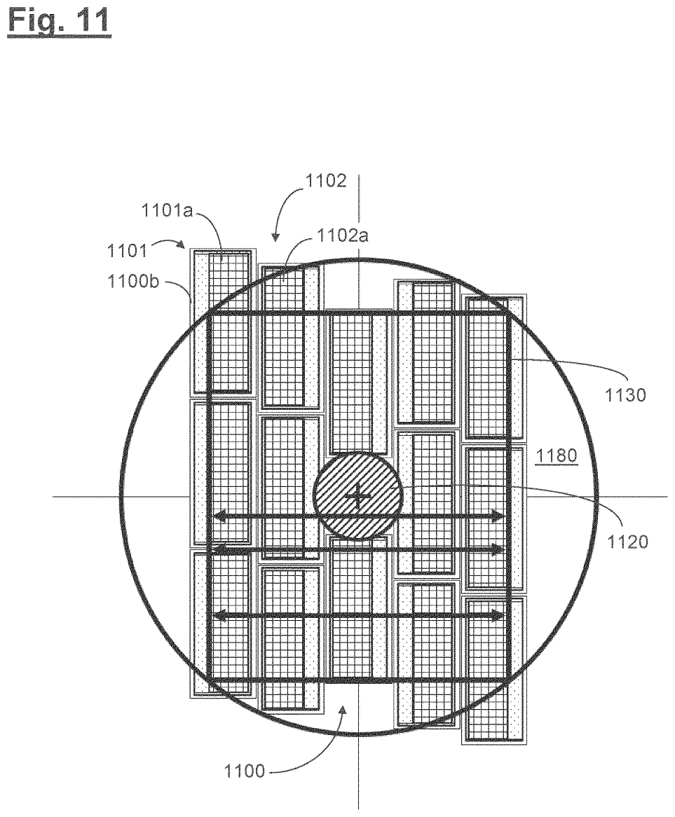

FIG. 11 shows an exemplary embodiment with a smaller image field in comparison with FIG. 10, in which case skillful geometric arrangement of the sensors achieves the effect that nevertheless each imaged mask region or each scan line sweeps over the active area of at least four sensors, where in comparison with FIG. 10 a higher line filling rate of 53% is attained here.

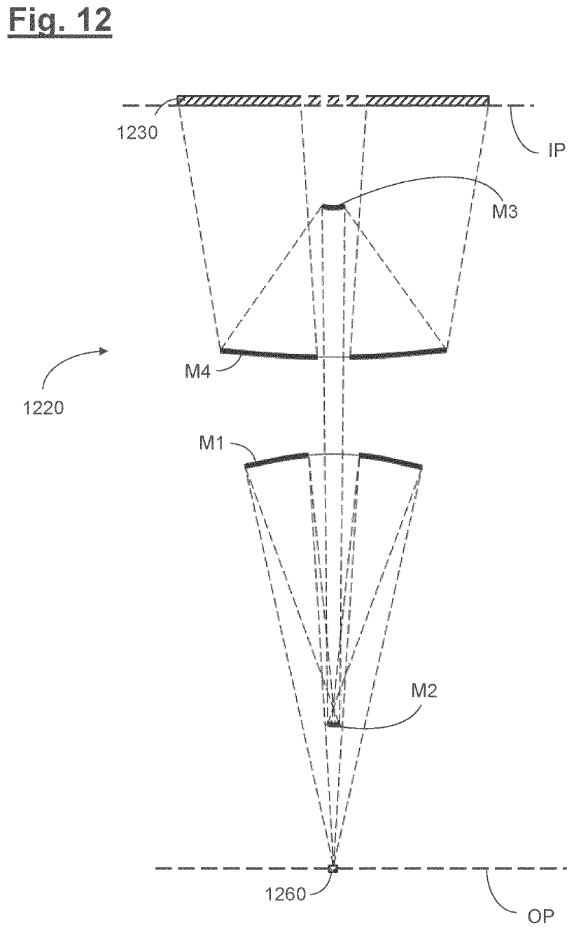

FIG. 12 shows a schematic illustration of the fundamental possible set-up of a projection lens 1220 used in a device according to the invention for mask inspection, which projection lens, as described above, generates an image field 1230 arranged symmetrically about the optical axis OA and is constructed from four mirrors M1-M4 in a so-called Schwarzschild design. In this case, in FIG. 12, an object field situated in the object plane OP of the projection lens 1220 is designated by “1260” and an image field situated in the image plane IP of the projection lens 1220 is designated by “1230”.

In the case of an image field arranged symmetrically about the optical axis OA and an obscuration situated in the center of this image field in accordance with the embodiments described above, the advantages according to the invention are manifested particularly well insofar as, by way of the suitable geometric arrangement of the sensors in combination with the scanning operation according to the invention, a disturbing influence of the obscuration on mask inspection can be avoided or at least alleviated. However, the invention is not restricted to applications with an image field arranged symmetrically about the optical axis and an obscuration situated in the center of this image field, but rather is also advantageously realizable in situations with an image field not arranged symmetrically about the optical axis.

In addition to the sensors of the sensor arrangement present in the embodiments described above, the device according to the invention can also comprise further sensors, which can serve for determining the relative movement of sensor arrangement and (EUV) optical unit with respect to one another in at least two degrees of freedom. This can take account of the circumstance that it is advantageous, in principle, for the sensor arrangement or camera not to be directly coupled to the EUV optical unit, in order that unwanted influences from the camera or sensor arrangement (for instance heat or vibrations caused by cooling fluid flows) do not directly affect the highly sensitive optical unit. A relative movement of the sensor arrangement in relation to the optical unit that takes place in this respect can then be measured by a measuring system (e.g. laser interferometers, capacitive sensors or optical position sensors (PSD sensors, PSD=“position sensitive device”)) in at least two degrees of freedom. The movement can then be taken into consideration computationally during the image processing and image evaluation, or the movement can be actively compensated for by a movement system, wherein this movement system can move the sensor arrangement or the mask stage carrying the mask. By way of the corresponding additional movement, the movement of the sensor arrangement (taking the imaging scale into consideration) can then ideally be precisely compensated for.

Even though the invention has been described on the basis of specific embodiments, numerous variations and alternative embodiments are evident to a person skilled in the art, e.g. through combination and/or exchange of features of individual embodiments. Accordingly, it goes without saying for a person skilled in the art that such variations and alternative embodiments are concomitantly encompassed by the present invention, and the scope of the invention is restricted only within the meaning of the appended patent claims and the equivalents thereof.

The present invention further comprises the aspects defined in the following clauses, which form part of the present description.
1. Method for mask inspection, wherein the mask is designed for operation in reflection at an operating wavelength of less than 30 nm and is intended to be illuminated in a lithography process in a projection exposure apparatus for exposing a wafer, wherein an object field situated in an object plane and illuminated with EUV radiation having a wavelength of less than 30 nm by way of an illumination system is imaged by a projection lens onto an image field situated in an image plane, wherein a sensor arrangement having a plurality of sensors is situated in the image, wherein the mask is guided over the object field in the object plane in a scanning operation, and wherein an image of the mask is formed by combining sensor images captured by each of the individual sensors in the scanning operation.
2. Method according to Clause 1, characterized in that as sensors of the sensor arrangement, TDI sensors are used in which only a part of the respective sensor area is embodied as active sensor area with active sensor pixels.
3. Method according to Clause 1 or 2, characterized in that in the scanning operation, the projections of different regions of the mask sweep over the sensor arrangement along different scan lines.
4. Method according to Clause 3, characterized in that a line filling rate, which is defined for each of said scan lines as a ratio between the distance covered in each case with active sensor pixels in the scanning operation and the image field length exposed in the scanning operation in the scanning direction, is in each case not less than 25% for any of the scan lines, in particular not less than 35% for any of the scan lines, more particularly not less than 50% for any of the scan lines.
5. Method according to Clause 3 or 4, characterized in that in the scanning operation for each of the scan lines the number of sensors swept over in each case is at least one, in particular at least two, more particularly at least three.
6. Method according to any of the preceding Clauses, characterized in that the sensors of the sensor arrangement form a plurality of sensor series arranged next to one another in the scanning direction and running transversely with respect to the scanning direction.
7. Method according to Clause 6, characterized in that in the scanning operation for each of the scan lines the number of sensor series not swept over in each case is at most two, in particular at most one.
8. Method according to Clause 6 or 7, characterized in that sensor series adjacent to one another are offset relative to one another in a direction running transversely with respect to the scanning direction.
9. Method according to Clause 8, characterized in that this offset is chosen such that at least one sensor of a sensor series partly overlaps two sensors of an adjacent sensor series.
10. Method according to any of Clauses 6 to 9, characterized in that the active sensor areas of the sensors are arranged asymmetrically on the respective sensor area, wherein the asymmetries of different sensors are oriented differently.
11. Method according to any of the preceding Clauses, characterized in that forming the sensor arrangement by combining the sensors involves carrying out sorting on the basis of a prior determination of defective regions of the respective sensors.
12. Method according to any of the preceding Clauses, characterized in that the projection lens generates an obscuration in the form of a region that is shaded during the imaging.
13. Method according to Clause 12, characterized in that the obscuration lies at least partly within the image field.
14. Method according to any of the preceding Clauses, characterized in that a readout of the data captured by each of the individual sensors in the scanning operation is synchronized with the guiding of the mask over the object field.
15. Method according to any of the preceding Clauses, characterized in that a calibration of the respective brightness of the sensor images captured by each of the individual sensors in the scanning operation is carried out on the basis of an intensity measurement carried out using an intensity sensor.
16. Method according to any of the preceding Clauses, characterized in that at least two sensors or sensor regions of the sensor arrangement are read at mutually different readout frequencies.
17. Method according to any of the preceding Clauses, characterized in that combining the sensor images of the sensors is preceded by preprocessing the sensor images.
18. Method according to any of the preceding Clauses, characterized in that the sensors are cooled for noise reduction purposes, in particular to a temperature below the average temperature of the projection lens.
19. Sensor arrangement comprising a plurality of sensors, wherein the sensors form a plurality of sensor series arranged next to one another in a predefined direction and running transversely with respect to the predefined direction, wherein a line filling rate, which is defined for each line running parallel to the predefined direction over a predefined image field, which is at least partly covered by the sensor arrangement, as a ratio between the distance covered in each case with active sensor pixels and the entire image field length in the predefined direction, is in each case not less than 25% for any of the lines.
20. Sensor arrangement according to Clause 19, characterized in that the line filling rate is not less than 35% for any of said lines, more particularly not less than 50% for any of said lines.
21. Sensor arrangement according to Clause 19 or 20, characterized in that the sensors are designed for an operating wavelength of less than 30 nm.
22. Sensor arrangement comprising a plurality of sensors, wherein the sensors form a plurality of sensor series arranged next to one another in a predefined direction and running transversely with respect to the predefined direction, wherein the sensors are designed for an operating wavelength of less than 30 nm.
23. Sensor arrangement according to any of Clauses 19 to 22, characterized in that the sensors are configured as TDI sensors.
24. Sensor arrangement according to any of Clauses 19 to 23, characterized in that sensor series adjacent to one another are offset relative to one another in a direction running transversely with respect to the predefined direction.
25. Sensor arrangement according to Clause 24, characterized in that this offset is chosen such that at least one sensor of a sensor series partly overlaps two sensors of an adjacent sensor series.
26. Sensor arrangement according to any of Clauses 19 to 25, characterized in that in the case of each of the sensors only a part of the respective sensor area is embodied as active sensor area with active sensor pixels.
27. Sensor arrangement according to Clause 26, characterized in that the active sensor areas are arranged asymmetrically on the respective sensor area, wherein the asymmetries of different sensors are oriented differently.
28. Sensor arrangement according to any of Clauses 19 to 27, characterized in that the sensor arrangement is formed by combining the sensors in such a way that the sensors are sorted on the basis of defective regions present on the respective sensors.
29. Sensor arrangement according to any of Clauses 19 to 28, characterized in that the sensor arrangement comprises a cooling device.
30. Sensor arrangement according to any of Clauses 19 to 29, characterized in that it is designed for use in a method according to any of Clauses 1 to 18.
31. Device for mask inspection, wherein the mask is designed for operation in reflection at an operating wavelength of less than 30 nm and is intended to be illuminated in a lithography process in a projection exposure apparatus for exposing a wafer, wherein the device comprises an illumination system, a projection lens and a sensor arrangement, wherein an object field situated in an object plane and illuminated with EUV radiation having a wavelength of less than 30 nm by way of the illumination system is imaged by a projection lens onto an image field situated in an image plane, wherein a sensor arrangement having a plurality of sensors is situated in the image plane, wherein the sensor arrangement is configured according to any of Clauses 19 to 30.
32. Device according to Clause 31, wherein the device is designed to carry out a method according to any of Clauses 1 to 18.

What is claimed is:

1. A method for mask inspection, wherein the mask is designed for operation in reflection at an operating wavelength of less than 30 nm and is intended to be illuminated in a lithography process in a projection exposure apparatus for exposing a wafer;
wherein an object field situated in an object plane and illuminated with EUV radiation having a wavelength of less than 30 nm by way of an illumination system is imaged by a projection lens onto an image field situated in an image plane, wherein a sensor arrangement having a plurality of sensors is situated in the image plane;
wherein the mask is guided over the object field in the object plane in a scanning operation;
wherein an image of the mask is formed by combining sensor images captured by each of the individual sensors in the scanning operation;
wherein in the scanning operation, the projections of different regions of the mask sweep over the sensor arrangement along different scan lines; and
wherein a line filling rate, which is defined for each of said scan lines as a ratio between the distance covered in each case with active sensor pixels in the scanning operation and the image field length exposed in the scanning operation in the scanning direction, is in each case not less than 25% for any of the scan lines.

2. The method according to claim 1, wherein time delay and integration (TDI) sensors having a sensor area are used as sensors of the sensor arrangement, and only a part of the respective sensor area is embodied as active sensor area with active sensor pixels.

3. The method according to claim 1, wherein the line filling rate is in each case not less than 35% for any of the scan lines.

4. The method according to claim 1, wherein in the scanning operation for each of the scan lines the number of sensors swept over in each case is at least one.

5. The method according to claim 1, wherein the sensors of the sensor arrangement form a plurality of sensor series arranged next to one another in the scanning direction and running transversely with respect to the scanning direction.

6. The method according to claim 5, wherein in the scanning operation for each of the scan lines the number of sensor series not swept over in each case is at most two.

7. The method according to claim 5, wherein sensor series adjacent to one another are offset relative to one another in a direction running transversely with respect to the scanning direction.

8. The method according to claim 7, wherein this offset is chosen such that at least one sensor of a sensor series partly overlaps two sensors of an adjacent sensor series.

9. The method according to claim 5, wherein active sensor areas of the sensors are arranged asymmetrically on the respective sensor area, wherein the asymmetries of different sensors are oriented differently.

10. The method according to claim 1, wherein forming the sensor arrangement by combining the sensors involves carrying out sorting on the basis of a prior determination of defective regions of the respective sensors.

11. The method according to claim 1, wherein the projection lens generates an obscuration in the form of a region that is shaded during the imaging.

12. The method according to claim 11, wherein the obscuration lies at least partly within the image field.

13. The method according to claim 1, wherein a readout of the data captured by each of the individual sensors in the scanning operation is synchronized with the guiding of the mask over the object field.

14. The method according to claim 1, wherein a calibration of the respective brightness of the sensor images captured by each of the individual sensors in the scanning operation is carried out on the basis of an intensity measurement carried out using an intensity sensor.

15. The method according to claim 1, wherein at least two sensors or sensor regions of the sensor arrangement are read at mutually different readout frequencies.

16. The method according to claim 1, wherein combining the sensor images of the sensors is preceded by preprocessing the sensor images.

17. The method according to claim 1, wherein the sensors are cooled for noise reduction purposes, in particular to a temperature below the average temperature of the projection lens.

18. A device for mask inspection, wherein the mask is designed for operation in reflection at an operating wavelength of less than 30 nm and is intended to be illuminated in a lithography process in a projection exposure apparatus for exposing a wafer, wherein the device comprises an illumination system, a projection lens and a sensor arrangement, wherein an object field situated in an object plane and illuminated with EUV radiation having a wavelength of less than 30 nm by way of the illumination system is imaged by a projection lens onto an image field situated in an image plane, wherein a sensor arrangement having a plurality of sensors is situated in the image plane, wherein the sensor arrangement comprises a plurality of sensors, wherein the sensors form a plurality of sensor series arranged next to one another in a predefined direction and running transversely with respect to the predefined direction, wherein a line filling rate, which is defined for each line running parallel to the predefined direction over a predefined image field, which is at least partly covered by the sensor arrangement, as a ratio between the distance covered in each case with active sensor pixels and the entire image field length in the predefined direction, is in each case not less than 25% for any of the lines.

19. The device according to claim 18, wherein the line filling rate is not less than 35% for any of said lines.

20. The device according to claim 18, wherein the sensors are designed for an operating wavelength of less than 30 nm.

21. A sensor arrangement comprising a plurality of sensors, wherein the sensors form a plurality of sensor series arranged next to one another in a predefined direction and running transversely with respect to the predefined direction, wherein the sensors are designed for an operating wavelength of less than 30 nm; wherein sensor series adjacent to one another are offset relative to one another in a direction running transversely with respect to the predefined direction

22. The sensor arrangement according to claim 21, wherein the sensors are configured as time delay and integration (TDI) sensors.

23. The sensor arrangement according to claim 21, wherein this offset is chosen such that at least one sensor of a sensor series partly overlaps two sensors of an adjacent sensor series.

25. The sensor arrangement according to claim 21, wherein each of the sensors has a sensor area, wherein in the case of each of the sensors only a part of the respective sensor area is embodied as active sensor area with active sensor pixels.

26. The sensor arrangement according to claim 25, wherein the active sensor areas are arranged asymmetrically on the respective sensor area, wherein the asymmetries of different sensors are oriented differently.

27. The sensor arrangement according to claim 21, wherein the sensor arrangement is formed by combining the sensors in such a way that the sensors are sorted on the basis of defective regions present on the respective sensors.

28. The sensor arrangement according to claim 21, wherein the sensor arrangement comprises a cooling device.

29. The sensor arrangement according to claim 21, wherein the sensor arrangement is designed for use in a method for mask inspection, wherein the mask is designed for operation in reflection at an operating wavelength of less than 30 nm and is intended to be illuminated in a lithography process in a projection exposure apparatus for exposing a wafer;
wherein an object field situated in an object plane and illuminated with EUV radiation having a wavelength of less than 30 nm by way of an illumination system is imaged by a projection lens onto an image field situated in an image plane, wherein a sensor arrangement having a plurality of sensors is situated in the image plane;
wherein the mask is guided over the object field in the object plane in a scanning operation;
wherein an image of the mask is formed by combining sensor images captured by each of the individual sensors in the scanning operation;
wherein in the scanning operation, the projections of different regions of the mask sweep over the sensor arrangement along different scan lines; and
wherein a line filling rate, which is defined for each of said scan lines as a ratio between the distance covered in each case with active sensor pixels in the scanning operation and the image field length exposed in the scanning operation in the scanning direction, is in each case not less than 25% for any of the scan lines.

30. The device according to claim 18, wherein the device is designed to carry out a method for mask inspection;
wherein the mask is guided over the object field in the object plane in a scanning operation;
wherein an image of the mask is formed by combining sensor images captured by each of the individual sensors in the scanning operation; and
wherein in the scanning operation, the projections of different regions of the mask sweep over the sensor arrangement along different scan lines.
